(19) United States
(12) Patent Application Publication
(10) Pub. No.: US 2012/0319144 A1
(43) Pub. Date: Dec. 20, 2012

(54) DISPLAY PANEL AND DISPLAY DEVICE

(75) Inventor: Yohsuke Fujikawa, Osaka (JP)

(73) Assignee: SHARP KABUSHIKI KAISHA, Osaka (JP)

(21) Appl. No.: 13/579,156

(22) PCT Filed: Nov. 5, 2010
(86) PCT No.: PCT/JP2010/069722

§ 371 Date: Aug. 15, 2012

(30) Foreign Application Priority Data
Feb. 23, 2010 (JP) 2010-037686

(51) Int. Cl. H01L 27/15

(52) U.S. Cl. 257/88; 257/E27.121

(57) ABSTRACT

Disclosed is a display panel 10 in which a TFT substrate 2 and an opposite substrate 3 are disposed so as to face each other. First electrode pads 18 and 18a are provided on the surface of the TFT substrate 2 facing the opposite substrate 3, and second electrode pads 15 and 15a are provided on the surface of the opposite substrate 3 facing the TFT substrate 2. At least portions of the first electrode pads 18 and 18a and the second electrode pads 15 and 15a overlap in a plan view. A black matrix 40 is provided in the opposite substrate 3. The second electrode pads 15 and 15a are provided in locations that do not overlap the black matrix 40 in a plan view. The first electrode pads 18 and 18a are provided on a protruding part 45 formed on the TFT substrate 2.

### TECHNICAL FIELD

The present invention relates to a display panel and a display device, and more particularly, to an active matrix-type display panel and display device provided with a resin black matrix.

### BACKGROUND ART

In recent years, liquid crystal display devices and organic electroluminescent (EL) display devices have replaced CRTs, and are widely used in various electronic devices such as televisions, monitors, and mobile telephones, taking advantage of characteristics such as high-definition, low energy consumption, thinness, and light weight.

Among such display devices, active matrix-type display devices, in which thin film transistors (hereinafter referred to as TFTs) are used as pixel switching elements, have a fast response time, allows multi-gradation display in a simple manner, and are thus widely used.

Active matrix-type display devices generally have a TFT substrate and an opposite substrate disposed so as to face each other, and a display element (liquid crystals, organic EL, or the like) is sealed between the substrates by a sealing material.

The configuration of an active matrix-type display device will be described below in detail based on FIG. 8.

FIG. 8 is a block diagram showing the schematic configuration of an active matrix-type display device.

As shown in FIG. 8, a display device 100 has a TFT substrate 102 and an opposite substrate 101 disposed so as to face each other.

The opposite substrate 101 is provided with an opposite electrode and a color filter layer, while the TFT substrate 102 is provided with pixel electrodes and TFT elements.

In order to decrease the size of a frame region and to improve reliability, the TFT substrate 102 has a scanning signal line driver circuit and a data signal line driver circuit formed monolithically thereon.

The TFT substrate 102 also has terminals that are formed by patterning a thin metal film in a terminal region 103, and the terminals and an external circuit board are electrically connected via a flexible printed circuit (FPC) 104 that is bonded by pressure onto the terminal region 103.

In the case of display devices with a relatively simple configuration such as a segment drive-type display device, a configuration in which terminals are formed on the substrate located on the display surface side of the display panel, that is, a substrate that corresponds to the opposite substrate in an active matrix-type display device, and in which the terminals are electrically connected to the external circuit board via a zebra connector (zebra rubber, anisotropic conductive rubber) is known.

In the case of an active matrix-type display device, a configuration in which circuits and wiring lines that are formed in the frame region of the display panel are shielded from light using a black matrix formed of a black photosensitive resin or the like is known.

### RELATED ART DOCUMENTS

### Patent Documents

Patent Document 1: Japanese Patent Application Laid-Open Publication No. 2001-222022 (Published on Aug. 17, 2001)
Patent Document 2: Japanese Patent Application Laid-Open Publication No. 2007-264447 (Published on Oct. 11, 2007)

### SUMMARY OF THE INVENTION

### Problems to be Solved by the Invention

However, in the display device 100 shown in FIG. 8, the FPC is expensive and needs to be aligned precisely with the terminals, which results in a problem of higher production unit cost and lower productivity.

Also, there is a problem that when a resin black matrix is provided, the black matrix has a thickness of around 1 μm, and therefore thin wiring lines that are formed on the surface of the black matrix and that cross the edge thereof are susceptible to disconnections.

The present invention was made in view of the above problems, and aims to provide a display panel and a display device in which disconnections are unlikely to occur even when provided with a black matrix, the display quality is high, the production unit cost is kept low, and the productivity is high.

### Means for Solving the Problems

In order to solve the issues described above, a display panel of the present invention, includes: a first substrate and a second substrate disposed to face each other; a first electrode pad provided on a surface of the first substrate facing the second substrate; and a second electrode pad provided on a surface of the second substrate facing the first substrate, wherein at least a portion of the first electrode pad and the second electrode pad overlap in a plan view, wherein the second substrate has a black matrix formed on the surface thereof facing the first substrate, wherein the second electrode pad is provided in a location that does not overlap the black matrix in a plan view, and wherein the first electrode pad is provided on a protruding part formed on the first substrate.

According to the above configuration, in the connection between the first electrode pad and the second electrode pad, disconnections of the conductors that form the connection do not occur at the edge of the black matrix. Therefore, a display panel with excellent reliability can be attained.

Because it becomes easier to set the clearance between the second electrode pad and the first electrode pad so as to be substantially the same as the clearance between the first substrate and the second substrate in other locations, unevenness resulting from an uneven clearance can be suppressed, thus improving display quality.

### Effects of the Invention

A display panel of the present invention, includes: a first substrate and a second substrate disposed to face each other; a first electrode pad provided on a surface of the first substrate facing the second substrate; and a second electrode pad provided on a surface of the second substrate facing the first substrate, wherein at least a portion of the first electrode pad and the second electrode pad overlap in a plan view, wherein the second substrate has a black matrix formed on the surface thereof facing the first substrate, wherein the second electrode pad is provided in a location that does not overlap the black matrix in a plan view, and wherein the first electrode pad is provided on a protruding part formed on the first substrate.

Therefore, there are no disconnections at the edge of the black matrix in the connection to the first electrode pad and the like, and a display panel with excellent reliability can be attained.

Because the clearance between the second electrode pad and the first electrode pad is made substantially the same as the clearance between the first substrate and the second substrate in other locations, it becomes possible to suppress unevenness resulting from an uneven clearance, and the display quality can be improved.

### BRIEF DESCRIPTION OF THE DRAWINGS

FIG. 1 shows a schematic configuration of a liquid crystal display device according to an embodiment of the present invention.

FIG. 2 is a plan view that shows a schematic configuration of an opposite substrate provided in the liquid crystal display device according to an embodiment of the present invention.

FIG. 3 shows a schematic configuration of a display panel provided in the liquid crystal display device according to an embodiment of the present invention.

FIG. 4 is a circuit diagram that shows the configuration of a protective circuit provided in the liquid crystal display device according to an embodiment of the present invention.

FIG. 5 is a plan view that shows the configuration of the vicinity of an input terminal of the display panel provided with the protective circuit of FIG. 4.

FIG. 6 is a cross-sectional view that shows the cross-sectional configuration of the display panel along the line A-A′ in FIG. 5.

FIG. 7 is a cross-sectional view that shows the cross-sectional configuration of the display panel along the line B-B′ in FIG. 3.

FIG. 8 is a block diagram that shows a schematic configuration of a conventional active matrix-type display device.

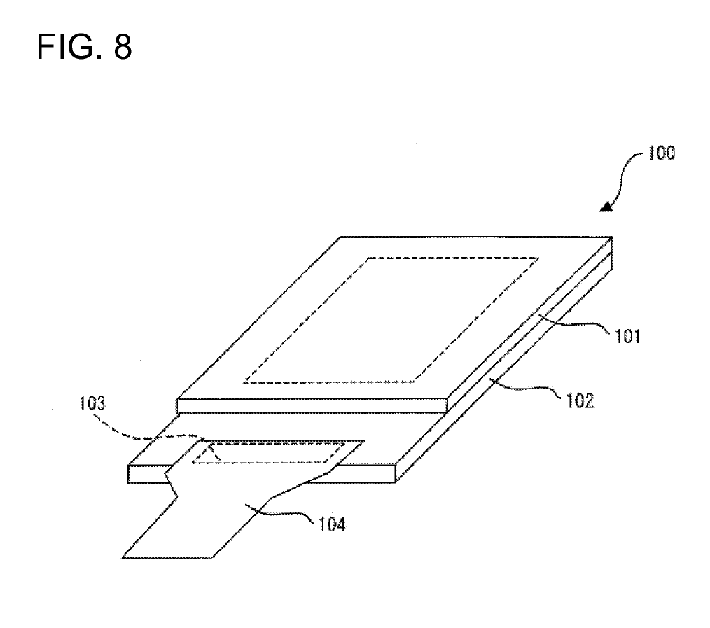

### DETAILED DESCRIPTION OF EMBODIMENTS

An embodiment of the present invention will be described in detail below based on the drawings. However, the dimensions, the materials, the shape, the relative arrangement, and the like of component parts disclosed in this embodiment are only one embodiment, and do not restrict the scope of the invention.

The display device of one embodiment of the present invention is not susceptible to disconnections even when provided with a black matrix, and the production unit cost is kept low while the productivity is high.

### Embodiment

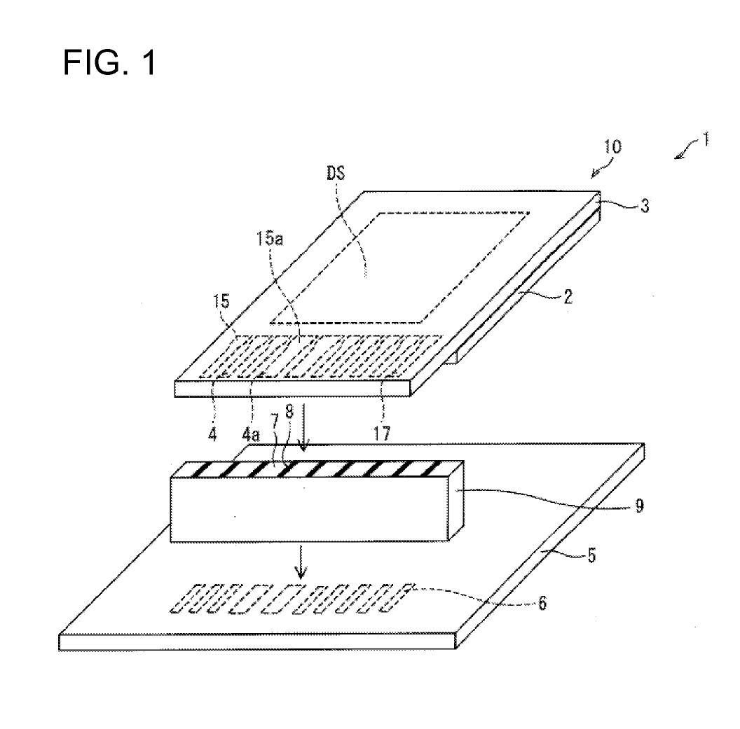

The configuration of a liquid crystal display device 1 of an embodiment of the present invention will be described below based on FIGS. 1 to 7.

The present embodiment describes a reflective liquid crystal display device 1 as an example of a display device, but is not limited to this, and can also be applied to a self-luminous display device, a transflective display device, a transmissive display device, or the like.

FIG. 1 is a block diagram that shows a schematic configuration of a liquid crystal display device 1 of one embodiment of the present invention.

As shown in FIG. 1, the liquid crystal display device 1 of the present embodiment is provided with a display panel 10 and an external circuit board (circuit board) 5.

The display panel 10 is provided with a TFT substrate 2 (first substrate), an opposite substrate 3 (second substrate), and a liquid crystal layer (not shown in the figure) sealed between the substrates 2 and 3. A plurality of TFT elements and pixel electrodes connected thereto are formed in the TFT substrate 2, and the TFT substrate 2 also has a scanning signal line driver circuit and a data signal line driver circuit formed monolithically therein. The opposite substrate 3 has an opposite electrode and a color filter formed therein. On the display panel 10, a display surface DS is on the side of the opposite substrate 3.

Also, in the display panel 10, a plurality of input terminals 4, 4a, and 17 (second substrate terminals) for inputting data signals, control signals, and power source signals are provided along one side edge portion of the surface of the opposite substrate 3 facing the TFT substrate 2. Second electrode pads 15 and 15a are provided for the respective input terminals 4, 4a, and 17.

As will be described later, data signals and control signals are inputted into the input terminals 4, voltage signals applied to the opposite electrode of the opposite substrate 3 are inputted into the input terminals 17, and power source signals are inputted into the input terminals 4a, which are formed wider than the input terminals 4 and 17. The input signals are then outputted to the scanning signal line driver circuit and data signal line driver circuit (driver circuits) on the TFT substrate 2.

The opposite substrate 3 extends as an overhang with respect to the TFT substrate 2 so as to expose the input terminals 4, 4a, and 17.

On the other hand, the external circuit board 5 is provided with a control circuit that outputs signals to control the display panel 10.

The external circuit board 5 is provided with a plurality of output terminals 6 that are arranged so as to face and overlap the corresponding input terminals 4, 4a, and 17 in a plan view.

The input terminals 4, 4a, and 17 and the output terminals 6 are electrically connected using a zebra connector 9, which has conductive strips 7 and insulating strips 8 provided in a stripe pattern and serves as an anisotropic conductive material. More specifically, the input terminals 4, 4a, and 17 and the output terminals 6, which form pairs, are electrically connected by respectively sandwiching the conductive strips 7 of the zebra connector 9.

The zebra connector 9 has a large pitch size, and therefore does not need to be aligned precisely. A connection can be made simply by stacking the input terminals 4, 4a, and 17 of the display panel 10, the zebra connector 9, and the output terminals 6 of the external circuit board 5 in that order, which makes it possible to provide a liquid crystal display device 1 that can keep the production unit cost low and that has high productivity.

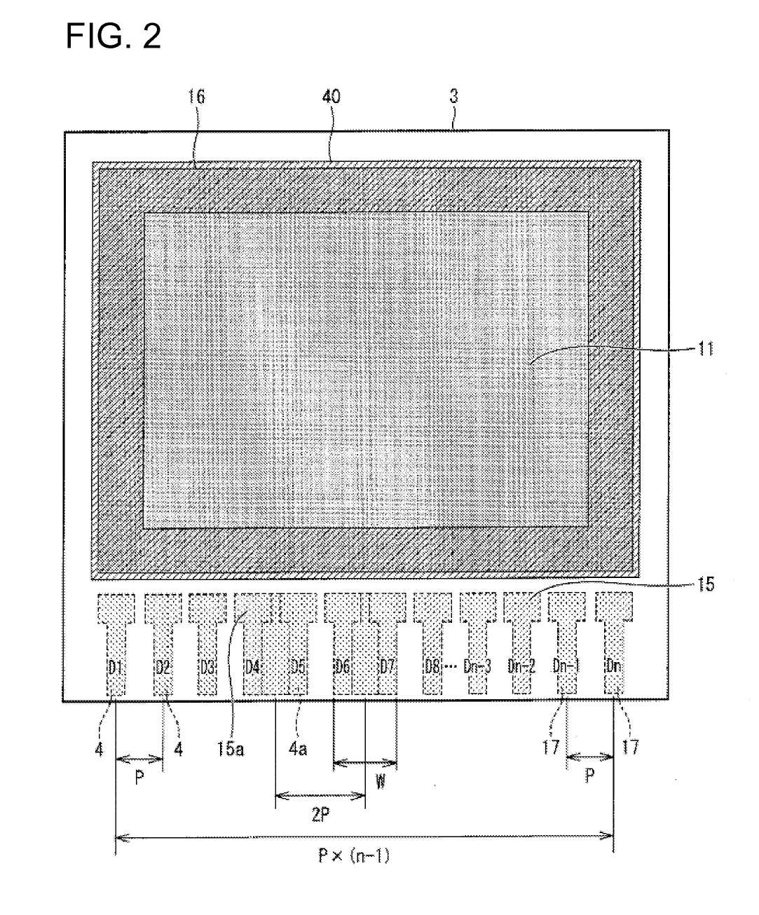

The configuration of the opposite substrate 3 will be described in further detail below based on FIG. 2.

FIG. 2 is a plan view that shows a schematic configuration of the opposite substrate 3 provided in the liquid crystal display device 1 of the present embodiment.

As shown in FIG. 2, an opposite electrode 16 made of a transparent electrode film such as indium tin oxide (ITO) or indium zinc oxide (IZO) is formed in the opposite substrate 3.

A prescribed color filter is provided in a display region 11 of the opposite substrate 3, and a black matrix 40 made of a black resin is provided in the frame region.

The plurality of input terminals 4, 4a, and 17, which are not electrically connected to the opposite substrate 3, are arranged along one edge of the opposite substrate 3, and the second electrode pads 15 and 15a are provided for the respective input terminals 4, 4a, and 17.

Here, the black matrix 40 is patterned so as not to overlap the input terminals 4, 4a, and 17 and the second electrode pads 15 and 15a in a plan view, as will be described later.

The input terminals 4, 4a, and 17 are preferably formed of the same material as that of the opposite electrode 16. With this configuration, the input terminals and the opposite electrode can be formed by patterning the same transparent electrode film.

In general, the conductive strips 7 and the insulating strips 8 provided in the zebra connector 9 have a relatively wide spacing therebetween, and it is most preferable to arrange the input terminals 4, 4a, and 17 so as to have the pitches corresponding to the spacing between the conductive strips 7 and the insulating strips 8 of the zebra connector 9.

In order to drive the scanning signal line driver circuit and the data signal line driver circuit, which are formed monolithically in the TFT substrate 2, it is necessary to input not only data signals and control signals, but also power source signals, and therefore, it is preferable that the input terminals 4a, to which the power source signals are inputted, be widened.

As shown in FIG. 2, the opposite substrate 3 has two input terminals 4a that are respectively for the high power source and for the low power source. The terminal width W thereof is greater than those of the other input terminals 4 and 17. With this configuration, malfunctions such as a voltage drop or the like can be prevented.

The input terminals 4 and 17 are each arranged with a pitch P while the input terminals 4a for the power source are arranged with a pitch 2P, and the input terminals 4a for the power source have a width W that is widened by the pitch P, but may be widened even further if necessary.

In the present embodiment, two widened input terminals 4a are provided, but the number of input terminals 4a may be adjusted as appropriate according to need.

As described above, in the liquid crystal display device 1, the pitch P and the width W of the input terminals 4, 4a, and 17 are set depending on the type of signal being inputted.

In the present embodiment, a configuration in which the opposite electrode 16 is provided on the opposite substrate 3 is described, but the present invention is not limited to this configuration, and can also be applied to a lateral electric field-type liquid crystal mode, such as the IPS mode, in which an opposite electrode is not provided on the opposite substrate 3, for example.

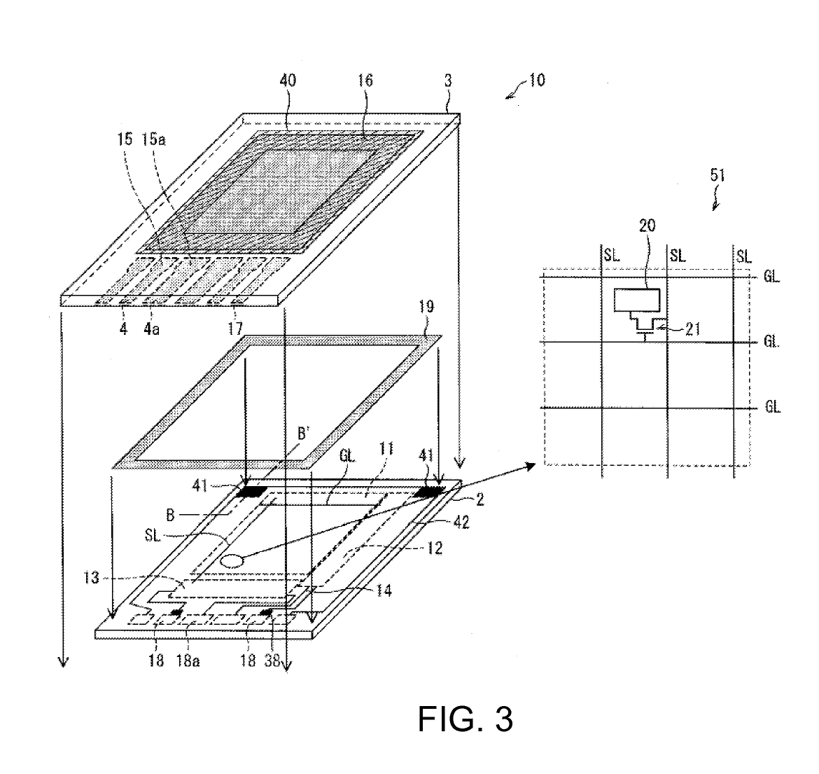

The configuration of the display panel 10 will be described below in further detail based on FIG. 3.

FIG. 3 is a block diagram that shows a schematic configuration of the display panel 10 provided in the liquid crystal display device 1 of the present embodiment.

As shown in FIG. 3, the TFT substrate 2 is provided with the following on the surface thereof facing the opposite substrate 3: a display region 11 in which a pixel circuit 51 is formed; and a frame region in which a scanning signal line driver circuit 12 and a data signal line driver circuit 13 are formed monolithically with polycrystalline silicon as the base. A plurality of pixel electrodes 20 and a plurality of TFT elements 21 are formed in a matrix in the pixel circuit 51.

In the present embodiment, polycrystalline silicon is used as the polycrystalline semiconductor film, but the material is not limited to this, and a semiconductor film formed by poly-crystallizing the following through laser annealing can be used: amorphous silicon; amorphous germanium; polycrystalline germanium; amorphous silicon-germanium; polycrystalline silicon-germanium; amorphous silicon carbide; polycrystalline silicon carbide; or the like.

The above-mentioned pixel electrode 20 is preferably light-reflective. According to this configuration, it is possible to attain a liquid crystal display device with high light-usage efficiency that can suppress rises in production unit cost and that has high productivity, whether the liquid crystal display device is a reflective display device or a transflective display device provided with light-reflective pixel electrodes 20.

The TFT substrate 2 is provided with a plurality of data signal lines SL and a plurality of scanning signal lines GL arranged so as to intersect with these data signal lines SL. The TFT elements 21 are provided at the respective intersections of the data signal lines SL and the scanning signal lines GL, and are controlled by the data signal lines SL and the scanning signal lines GL.

Here, the data signal of an image to be displayed in the display panel 10 is outputted from some of the output terminals 6, which are provided on the external circuit board 5 shown in FIG. 1. The data signal is image data that represents the display state of each pixel, and is generated based on image data sent in a time-shared manner. The other plurality of output terminals 6 output a source clock signal and a source start pulse signal to the data signal line driver circuit 13 as the timing signals to display the data signal correctly in the display panel 10, and also output a gate clock signal and a gate start pulse signal to the scanning signal line driver circuit 12.

The scanning signal line driver circuit 12 selects the plurality of scanning signal lines GL sequentially in sync with timing signals such as the gate clock signal. The data signal line driver circuit 13 operates in sync with timing signals such as the source clock signal, determines a timing that corresponds to each data signal line SL, samples the data signal with each timing, and writes in the signal in accordance with the sampling result to each data signal line SL.

The pixels of the display panel 10 display an image in accordance with data outputted from the respective corresponding data signal lines SL when the respective corresponding scanning signal lines GL are selected.

Common transfer electrodes 41 are provided on both corners of one side (short side) of the TFT substrate 2, and are electrically connected to common transfer wiring lines 42 formed along the edges of opposing sides (long sides), respectively.

The opposite electrode 16 and the common transfer electrodes 41 are electrically connected by conductive members such as gold particles contained in a sealing material 19, as will be described below.

Wiring lines (signal lines, power source lines) 14 are led out toward the outside of the TFT substrate 2 from the scanning signal line driver circuit 12 and the data signal line driver circuit 13. The driver circuits 12 and 13, protective circuits 38, which will be explained below, and first electrode pads 18 and 18a provided on the TFT substrate 2 are electrically connected in this order.

The common transfer wiring lines 42 are also electrically connected to the first electrode pads 18 provided on the TFT substrate 2.

In other words, the first electrode pad 18 or 18a is provided for each and every wiring line 14 and common transfer wiring line 42 led out to the outside of the TFT substrate 2, and the first electrode pads 18 and 18a are arranged along one side edge portion of the TFT substrate 2.

On the other hand, as already mentioned, the input terminals 4, 4a, and 17, which are electrically disconnected from the opposite electrode 16, are formed along one edge of the opposite substrate 3, and the second electrode pad 15 or 15a accompanies each individual input terminal 4, 4a, and 17.

The number of first electrode pads 18 and 18a is the same as the number of second electrode pads 15 and 15a, and when viewing the display panel 10 in a plan view, the second electrode pads 15 and 15a and the first electrode pads 18 and 18a are formed so as to overlap each other one-to-one.

On the opposite substrate 3, the second electrode pads 15a, which are provided on the widened input terminals 4a described above, are formed so as to be wider than the other second electrode pads 15. The first electrode pads 18a, which face these second electrode pads 15a, are also formed so as to be wider than the other first electrode pads 18.

The sealing material 19, which contains conductive members that allow conductivity between the second electrode pads 15 and 15a and the first electrode pads 18 and 18a, will be described later.

Here, the number of input terminals 4, 4a, and 17, the number of second electrode pads 15 and 15a, and the number of first electrode pads 18 and 18a shown in FIGS. 1 to 3 are only given as an example, and the numbers may be adjusted as appropriate according to need.

According to the above configuration, the scanning signal line driver circuit 12 and the data signal line driver circuit 13 are formed monolithically in the TFT substrate 2, and therefore, it is possible to decrease the number of input terminals 4 and 4a, and to increase the pitch thereof. As a result, the pitches of the second electrode pads 15 and 15a and the first electrode pads 18 and 18a, made to correspond to the input terminals 4 and 4a, can also be increased. Therefore, the areas that can be allocated respectively to the second electrode pads 15 and 15a and the first electrode pads 18 and 18a can be increased.

Therefore, a liquid crystal display device 1 that can sufficiently decrease the conduction resistance between the second electrode pads 15 and 15a and the first electrode pads 18 and 18a can be attained.

There is no need to use an expensive FPC or the like to connect the display panel 10 to the output terminals 6 of the external circuit board 5; a low cost zebra connector 9 that have fewer corresponding terminals and that have a relatively large pitch size between the terminals can be used.

In the present embodiment, the pixel electrodes 20 provided in the TFT substrate 2 are formed of a material with low electrical resistance and high reflectivity such as aluminum or silver, but the material thereof is not limited to these.

Memory elements may be built in below the pixel electrodes 20, which are light reflective and provided for the respective pixels, so as to make a display device with low electricity consumption. SRAM is one example of the memory element. In the case of SRAM, 1 bit per pixel may be used, or a plurality of SRAMs may be provided for each pixel if doing gradation display. Such a display devices in which each pixel is equipped with SRAM only requires a small power source capacity and current value, and is therefore suitable for use of the zebra connector 9 for the terminal connection.

In the present embodiment, the common transfer electrodes 41 are arranged in both corners of one side, but the arrangement is not limited to this; the arrangement and number of common transfer electrodes may be determined as appropriate. A total of four common transfer electrodes may be arranged in the four corners of the TFT substrate 2, or in the case of a small display panel, one common transfer electrode may be provided, for example.

The sealing material 19 will be described in detail below.

The sealing material 19 serves as a seal of the display device by bonding the TFT substrate 2 and the opposite substrate 3 with a prescribed spacing therebetween, and is formed along the perimeter of the TFT substrate 2 in a frame shape. The liquid crystal material is injected into the inner space surrounded by the sealing material 19.

For the sealing material 19, an ultraviolet-curable resin, a thermosetting resin, or a combined resin thereof can be used, for example.

The sealing material 19 contains conductive members such as gold particles. As a result of the conductive members, the second electrode pads 15 and 15a are electrically connected to the first electrode pads 18 and 18a. The second electrode pads 15 and the first electrode pads 18 and 18a are provided in the peripheral part of the display panel 10 where the sealing material 19 is formed.

The opposite electrode 16 and the common transfer electrodes 41 are electrically connected as a result of the conductive members.

Specifically, the opposite electrode 16 is connected to the common transfer wiring lines 42 on the TFT substrate 2 via the common transfer electrodes 41. The common transfer wiring lines 42 have a wiring path that leads to the input terminals 17 on the opposite substrate 3 after passing through the first electrode pads 18.

According to the above configuration, the step of forming the sealing material 19 to bond the TFT substrate 2 to the opposite substrate 3 with a prescribed spacing therebetween, and the step of forming the conductive members to electrically connect the second electrode pads 15 and 15a to the first electrode pads 18 and 18a can be combined into one step, and a highly productive liquid crystal display device 1 can be attained.

If the opposite electrode 16 and the input terminals 17 for applying a voltage thereto are directly connected electrically on the opposite substrate 3, the connective path therebetween is made to pass through the black matrix 40, increasing the susceptibility to disconnections. However, with the above configuration, the susceptibility to disconnections is low.

Here, the conductive members have resistance, but because the areas of the second electrode pads 15 and 15a and the first electrode pads 18 and 18a are large, the resistance can be kept to a level in which circuit operation is not impeded.

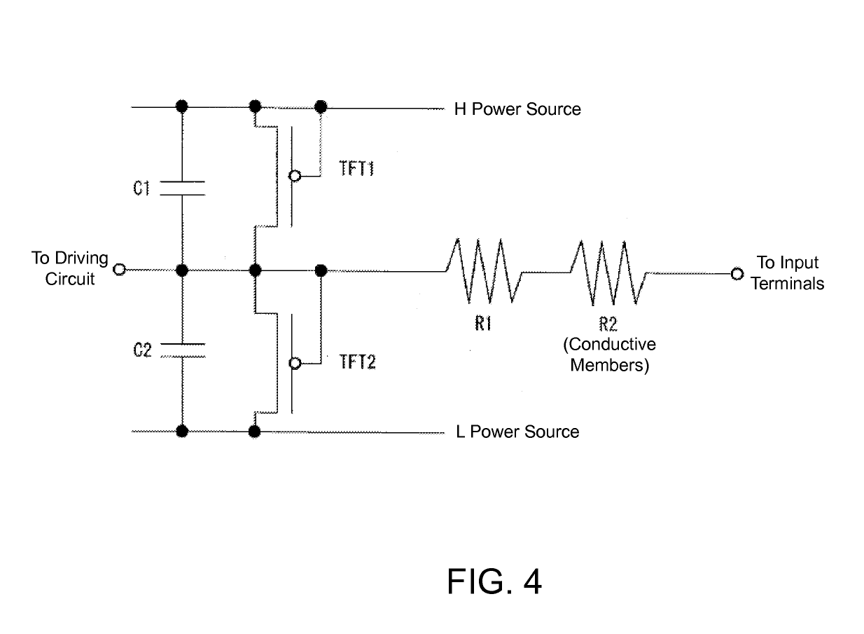

The protective circuit 38 will be described in detail below based on FIG. 4.

FIG. 4 is a circuit diagram that shows one example of the protective circuit 38 provided in the liquid crystal display device 1 of the present embodiment.

As described above, the surface of the TFT substrate 2 facing the opposite substrate 3 has the driver circuits 12 and 13, the protective circuits 38, and the first electrode pads 18 formed monolithically thereon so as to be electrically connected in that order.

According to the above configuration, damage to TFT elements provided in the driver circuits 12 and 13 due to static electricity or noise currents coming in from the plurality of input terminals 4 can be prevented.

As shown in FIG. 4, the protective circuit 38 is provided with two TFT elements (TFT 1 and TFT 2) formed through the same manufacturing process as the TFT elements 21 provided in the display region 11.

The drain electrode of one of the TFT elements (TFT 1) is connected to a high power source (H power source), and the source electrode is connected to the wiring line that goes from the input terminal 4 to the driver circuits 12 or 13, which is to be protected. The TFT element (TFT 1) has a configuration in which the drain electrode and the gate electrode are connected, and shows characteristics of a diode.

In other words, the circuit is configured such that if, as a result of static electricity or the like, a voltage that is equal to or higher than the H power source is applied to the wiring line, the TFT element (TFT 1) turns on, and allows the abnormal current to be discharged.

The drain electrode of the other TFT element (TFT 2) is connected to the wiring line that goes from the input terminal 4 to the driver circuit 12 or 13, which is to be protected, and the source electrode is connected to the low power source (L power source). The TFT element (TFT 2), like the TFT 1, has a configuration in which the drain electrode and gate electrode are connected, and shows characteristics of a diode.

As a result, the circuit is configured such that if a voltage that is equal to or lower than the L power source is applied to the wiring line, the TFT element (TFT 2) turns on, and the current flows from the L power source.

Therefore, according to the above configuration, the voltage applied to the wiring lines can always be kept at or below that of the H power source and at or above that of the L power source, thus preventing damage to the TFT elements and the like provided in the driver circuits 12 and 13.

The protective circuit 38 is provided with resistors R1 and R2 as an example of resistors on the wiring line. Capacitors C1 and C2 are provided between the wiring line and the H power source, and between the wiring line and the L power source, respectively.

As a result, even if there is a voltage spike in the wiring lines, damage to the TFT elements (TFT 1 and TFT 2) can be prevented.

In the present embodiment, the protective circuit 38 with a configuration such as that shown in FIG. 4 is provided, but the configuration is not limited to this, and may be changed as appropriate. Protective circuits or the like that are constituted of resistors and transistors can be used as appropriate, for example.

The protective circuits 38 can be provided in a plurality of locations on the surface of the TFT substrate 2 facing the opposite substrate 3, such as inside the driver circuits 12 and 13.

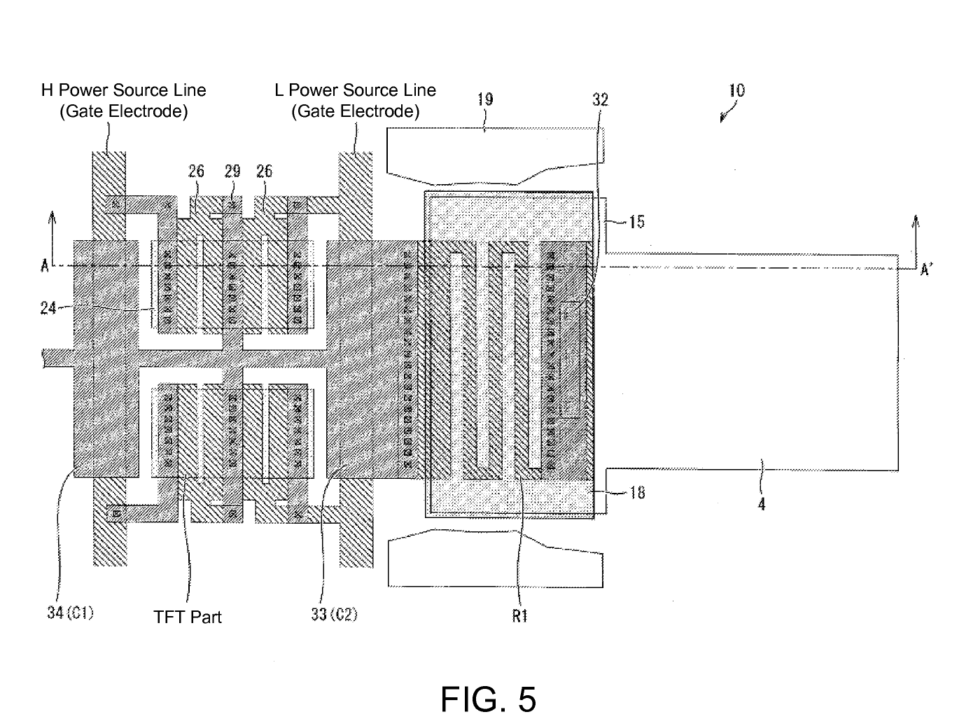

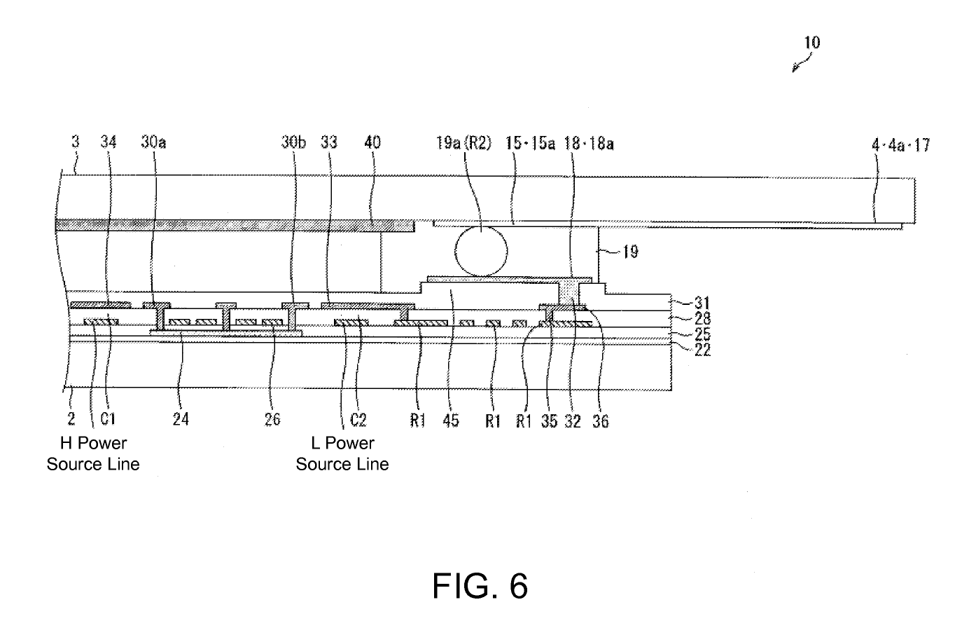

The configuration of the vicinity of the input terminals 4 of the display panel 10 will be described in further detail below based on FIGS. 5 and 6.

FIG. 5 is a plan view that shows the configuration of the vicinity of the input terminal 4 of the display panel 10, which is provided with the protective circuit 38 of FIG. 4.

As shown in FIG. 5, the components from the driver circuits 12 and 13 to the input terminal 4 are connected in the following order: the driver circuits 12 and 13, the protective circuits 38, the first electrode pads 18, conductive members 19a in the sealing material 19, the second electrode pads 15, and the input terminals 4.

According to the above configuration, because the protective circuits 38 are formed on the inner side of the sealing material 19, it is possible to protect the protective circuits 38 from damage or corrosion from the outside.

FIG. 6 is a cross-sectional view that shows the cross-sectional configuration of the display panel 10 along the line A-A′ in FIG. 5.

As shown in FIG. 6, a base film 22 is formed on the TFT substrate 2, and on the base film 22, a semiconductor film 24 is provided to correspond to where a TFT part shown in FIG. 5 is formed.

A gate insulating film 25 is formed on the base film 22, and the semiconductor film 24 is covered by the gate insulating film 25.

Gate electrodes 26, an L power source line, and an H power source line are formed on the gate insulating film 25 by patterning the same metal layer.

The gate electrodes 26, the L power source line, and the H power source line are covered by an interlayer insulating film 28 (insulating layer).

Metal films 33 and 34, a source electrode 30a, and a drain electrode 30b are formed on the interlayer insulating film 28 by patterning the same metal layer.

The metal film 33 is connected to the resistor R1 via a contact hole 35 formed in the interlayer insulating film 28.

The resistor R1 is formed so as to have the desired resistance value by patterning the metal layer for forming the gate electrode 26 so as to form a meandering shape.

The capacitor C1 is formed by the metal film 34 and the H power source line, and the capacitor C2 is formed by the metal film 33 and the L power source line.

The resistor R1 is electrically connected to an intermediate metal film 36, which is electrically connected to the first electrode pads 18, via the contact hole 35 formed in the interlayer insulating film 28.

The intermediate metal film 36 is formed by patterning the metal layer for forming the metal films 33 and 34.

The metal films 33 and 34 and the intermediate metal film 36 are covered by a protective insulating film 31 (insulating layer).

The first electrode pads 18 and 18a are formed above the intermediate metal film 36 and on the protective insulating film 31.

On the protective insulating film 31, a protruding part 45 is formed in the region where the first electrode pads 18 and 18a are formed, and the first electrode pads 18 and 18a have a higher surface than the surrounding area.

The protruding part 45 is formed by creating a localized area with a different thickness in the protective insulating film 31.

If the protective insulating film 31 is formed of a positive-type photosensitive resin, for example, the protruding part 45 may be formed by conducting a half exposure with shortened exposure time in which the protruding part 45 is completely shielded from light and the other parts are covered by a transmissive photomask. Alternatively, the protruding part 45 may be formed by conducting an exposure in which the protruding part 45 is completely shielded from light while the other parts are covered by a halftone or gray-tone photomask.

Also, it is possible to divide the formation of the protective film into two steps in which the first step involves forming the protective film on the entire surface of the TFT substrate 2 and the second step involves forming the protective film only on the region where the first electrode pads 18 are to be formed, thus forming the protruding part 45. However, this increases the production unit cost.

The intermediate metal film 36 and the first electrode pads 18 and 18a are electrically connected via through-holes 32 (contact holes) formed in the protective insulating film 31.

The sealing material 19 is provided so as to cover the first electrode pads 18. The second electrode pads 15 and 15a, which will be described later, are electrically connected to the first electrode pads 18 and 18a via the conductive members 19a (resistors R2) contained in the sealing material 19.

The input terminals 4, 4a, and 17 are formed on the surface of the opposite substrate 3 facing the TFT substrate 2, and the second electrode pads 15 and 15a are attached to the individual terminals 4a and 17. Also, a black matrix 40 is formed on the surface of the opposite substrate 3 facing the TFT substrate 2 so as not to cover the input terminals 4, 4a, and 17 and the second electrode pads 15 and 15a.

In other words, the region where the protruding part 45 is formed and the region where the black matrix 40 is not formed face one another in the region where the first electrode pads 18 and 18a are formed.

The thickness of the protruding part 45 (in other words, the difference in height between the highest surface of the protruding part 45 and the surface of the surrounding area) is the same as the thickness of the black matrix 40.

According to the above configuration, it is possible to make the clearance between the second electrode pads 15 and 15a and the first electrode pads 18 and 18a substantially the same as the clearance between the other areas of the TFT substrate 2 and the opposite substrate 3.

As a result, the clearance between the TFT substrate 2 and the opposite substrate 3 can be kept the same throughout the perimeter of the display panel 10.

Therefore, unevenness resulting from an uneven clearance can be suppressed, thus improving the display quality.

What is meant by the thickness of the protruding part 45 being the same as the thickness of the black matrix 40 is that the difference in thickness therebetween may be within a margin that does not result in the appearance of unevenness, and may be determined from the dimensions of the frame of the display panel 10, for example. If the frame is large, sudden changes in clearance can be mitigated, so the thickness of the protruding part 45 may be greater than the thickness of the black matrix 40, or the thickness of the protruding part 45 may be smaller than the thickness of the black matrix 40, for example.

In the present embodiment, because the driver circuits 12 and 13 are formed monolithically within the display panel 10, the frame of the display panel 10 on the side where the terminals are formed becomes larger. As a result, the distance between the display region 11 and the protruding part 45 becomes greater.

In this case, even if the thickness of the protruding part 45 differed slightly from the thickness of the black matrix 40, this would rarely affect the display region 11 so as to degrade display quality in the form of unevenness. Therefore, the combination of the display panel 10 provided with the driver circuits and the protruding part 45 works well.

Also, the connection to the input terminals 4, 4a, and 17 or the second electrode pads 15 and 15a does not experience disconnections at the edge of the black matrix 40, and therefore, a liquid crystal display device 1 with excellent reliability can be attained.

As described above, the second electrode pads 15 and 15a are connected to the resistor R1 via the contact holes 35 and the through-holes 32 provided in the interlayer insulating film 28 and the protective insulating film 31. In other words, the second electrode pads 15 and 15a are disposed in a layer above the resistor R1 so as to overlap therewith through the interlayer insulating film 28 and/or the protective insulating film 31. As a result, the area of the protective circuit 38 and the second electrode pads 15 and 15a can be kept small.

As a result, the frame of the display panel 10 provided in the liquid crystal display device 1 can be kept small.

According to the above configuration, even if contaminants enter the interlayer insulating film 28 and the protective insulating film 31 during the formation of the contact holes 35 and the through-holes 32, thereby causing a short circuit between second electrode pads 15 and 15a and the resistor R1, because the short circuit occurs within the same wiring lines, the effects are limited to a change in resistance of the resistor R1, and would rarely affect the operation of the driver circuits 12 and 13.

Alternatively, a configuration that omits the protective insulating film 31, the through-holes 32, and the intermediate metal film 36 and that instead has the first electrode pads 18 and 18a formed on the interlayer insulating film 28 may be used. However, from the standpoint of guaranteeing that the first electrode pads 18 and 18a are effectively separated from the resistor R1 and maintaining the resistance of the resistor R1 at an appropriate level, it is preferable to form the interlayer insulating film 28 and the protective insulating film 31. By providing the interlayer insulating film 28 and the protective insulating film 31, it becomes possible to reliably reduce the probability that a short circuit occurs between the first electrode pads 18 and 18a and the resistor R1 over the double-layered insulating layer.

This effect can also be attained by providing a single insulating layer having a sufficient thickness. However, this configuration poses a problem of requiring more time to form the film and making it more difficult to conduct fine patterning such as forming a large number of through-holes in the insulating layer.

In the liquid crystal display device 1, it is preferable that the second electrode pads 15 and 15a and the pixel electrodes 20 be made of the same material and formed by patterning the same layer.

In the liquid crystal display device 1, it is preferable that the first electrode pads 18 and 18a and the opposite electrode 16 be made of the same material and formed by patterning the same layer.

According to the above configuration, the second electrode pads 15 and 15a and the pixel electrodes 20 provided in the TFT substrate 2, or the first electrode pads 18 and 18a and the opposite electrode 16 provided in the opposite substrate 3 can be made of the same material, and can be patterned into a prescribed shape at the same time.

As a result, a liquid crystal display device 1 with a smaller number of manufacturing steps and with high productivity can be attained.

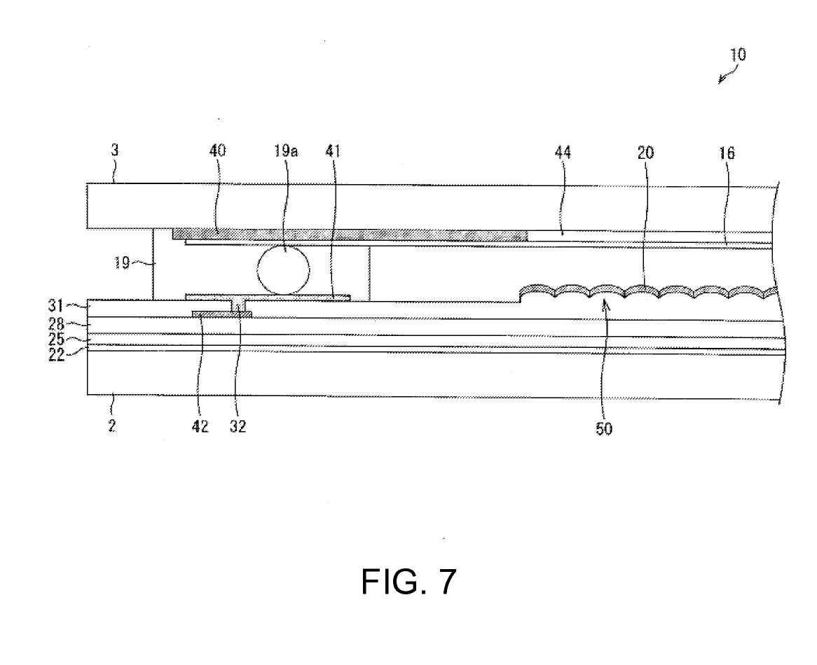

FIG. 7 is a cross-sectional view that shows the cross-sectional configuration of the display panel 10 along the line B-B′ in FIG. 3.

As shown in FIG. 7, the black matrix 40 is provided in the frame region on the surface of the opposite substrate 3 facing the TFT substrate 2, and a color filter 44 is provided in the display region 11.

The opposite electrode 16 is formed of a transparent electrode film made of ITO or the like on the surface of the black matrix 40 and the color filter 44 facing the TFT substrate 2.

The color filter 44 does not have to be made of the typical three colors RGB. In the case of a black and white display, for example, a color filter 44 that is lightly colored in order for color adjustments to be made for displaying white may be used.

The liquid crystal alignment mode used in reflective liquid crystal display devices often requires a narrow gap (cell gap) of around 2 μm between the first substrate (TFT substrate) and the second substrate (opposite substrate). However, due to reasons related to the manufacturing steps, there are cases in which it is difficult to bond the first substrate and the second substrate with such a narrow gap, in which case the whites in the display often take on a yellow tinge, which is unattractive to consumers. In such cases, it is preferable to use a color filter that is lightly colored for color adjustment as described above and that is around the same thickness as the black matrix.

On the other hand, the base film 22, the gate insulating film 23, and the interlayer insulating film 28 are laminated on the TFT substrate 2 in this order, and the common transfer wiring line 42 is formed on the interlayer insulating film 28.

The common transfer wiring line 42 is covered by the protective insulating film 31, and the common transfer electrode 41 is formed on the protective insulating film 31.

The common transfer wiring line 42 and the common transfer electrode 41 are electrically connected via the through-hole 32.

As described above, the common transfer electrode 41 and the opposite electrode 16 are electrically connected via the conductive member 19a.

The protective insulating film 31 is made of a photosensitive resin, and an uneven part 50 is formed in the display region 11. The pixel electrode 20 made of a substance with a high reflectivity such as aluminum and silver is formed in the layer above the uneven part 50. According to this configuration, a reflective liquid crystal display device 1 provided with excellent reflectivity due to scattered reflection from the unevenness of the surface can be attained.

In the present embodiment, the pixel electrodes 20 are formed of a highly reflective substance such as aluminum or silver, but the present invention is not limited to this; a reflective film may be provided separately on the pixel electrodes 20, for example.

It is preferable that the protruding part 45 under the first electrode pads 18 and 18a be formed simultaneously with the uneven part 50. As a result, the liquid crystal display device 1 of the present invention can be attained without raising the production unit cost thereof. Even in a configuration without the uneven part 50, it is possible to form the protruding part 45, and it is apparent that the presence or lack of the uneven part 50 does not affect the formation of the protruding part 45.

The present invention is not limited to the embodiment described above, and various modifications can be made without departing from the scope of the claims. Therefore, embodiments obtained by appropriately combining the techniques disclosed in different embodiments are included in the technical scope of the present invention.

It is preferable that the display panel of the present invention include an insulating layer in the first substrate, wherein the protruding part has a higher surface formed by increasing a thickness of the insulating layer.

According to the above configuration, the protruding part can be formed with ease, and therefore, a display panel that can suppress a rise in production unit cost and that has a high productivity can be attained.

In the display panel of the present invention, the thickness of the protruding part is preferably the same as that of the black matrix.

According to the above configuration, the clearance between the second electrode pads and the first electrode pads can be made substantially the same as the clearance between other areas of the first substrate and the second substrate. As a result, unevenness resulting from an uneven clearance can be suppressed, and the display quality can thus be improved.

In the display panel of the present invention, it is preferable that the first substrate and the second substrate be bonded to each other via a sealing material, wherein the sealing material contains a conductive member, and wherein the first electrode pad and the second electrode pad are connected via the conductive member.

According to the above configuration, the sealing material, which bonds the first substrate and the second substrate to each other with a prescribed gap therebetween, contains conductors (conductive members) such as gold particles. This makes it possible to combine the step of forming the sealing material and the step of electrically connecting the first electrode pads to the second electrode pads into one step, and as a result, a display panel with a high productivity can be attained.

It is preferable that the display panel of the present invention include a pixel circuit and a driver circuit in the first substrate, the driver circuit being provided for driving the pixel circuit, wherein the driver circuit is connected to the first electrode pad, and wherein the driver circuit is connected to the second electrode pad via the first electrode pad and the conductive member.

According to the above configuration, the driver circuit of the first substrate can be electrically connected to the second substrate with ease.

In the display panel of the present invention, it is preferable that the driver circuit be formed monolithically.

According to the above configuration, the driver circuit is formed monolithically, which makes it possible to minimize the size of the driver circuit. As a result, it is possible to increase the area of the first electrode pad.

Therefore, any resistance that is generated when electrically connecting the first electrode pads to the second electrode pads can be kept at a level in which the operation of the circuit is not affected.

Also, there is no need to use a high cost FPC to connect the first electrode pads to the second electrode pads.

In the display panel of the present invention, it is preferable that the driver circuit and the first electrode pad be connected via a protective circuit.

According to the above configuration, it is possible to prevent damage from static electricity or noise currents coming in from the outside to the active elements provided in the driver circuits.

In the display panel of the present invention, it is preferable that the protective circuit be provided with a resistor, wherein the first electrode pad and the resistor overlap each other in a plan view through an insulating layer.

According to the above configuration, it is possible to reduce the area of the protective circuit and the first electrode pad, and to minimize the size of the frame of the display panel.

With the above configuration, even if contaminants enter the insulating layer and cause a short circuit between the first electrode pads and the resistors, because the short circuit occurs within the same wiring line, the effect is limited to a change in resistance of the resistors. Therefore the effect on the operation of the driver circuits is minimal.

In the display panel of the present invention, it is preferable that the protective circuit be provided with a resistor, a transistor, and a capacitor.

According to the above configuration, even if a voltage spike occurs in the liquid crystal panel, it is possible to prevent damage to the transistor provided in the protective circuit, and it is possible to prevent damage from static electricity or noise currents coming in from the outside to the active elements provided in the driver circuits.

It is preferable that the display panel of the present invention include an opposite electrode in the second substrate and a common transfer electrode in the first substrate, wherein the common transfer electrode is connected to the first electrode pad, and wherein the opposite electrode and the common transfer electrode are connected via the conductive member.

If the opposite electrode and the second electrode pad for applying voltage thereto are electrically connected directly on the opposite substrate, the connective path therebetween is made to pass through the black matrix, thus increasing the susceptibility to disconnections, while the above configuration is not susceptible to such disconnections.

In the display panel of the present invention, it is preferable that the second electrode pad and the opposite electrode be formed by patterning the same layer.

According to the above configuration, a display device with fewer manufacturing steps and with a high productivity can be attained.

It is preferable that the display panel of the present invention include a reflective electrode in the first substrate and an uneven part between the first substrate and the pixel electrode, wherein the protruding part and the uneven part are formed of the same material.

According to the above configuration, a display panel with fewer manufacturing steps and with high productivity can be attained.

In the display panel of the present invention, the above material is a photosensitive resin.

According to the above configuration, the protruding part and the uneven part can be formed with ease through photo-processing.

The display device of the present invention includes: the above-mentioned display panel; and a circuit board, wherein the second substrate has a second substrate terminal connected to the second electrode pad, and wherein the second substrate terminal has a part that does not overlap the first substrate in a plan view.

According to the above configuration, signals from the circuit board can easily be inputted to the display panel by electrically connecting the display panel to the circuit board via the second substrate terminal.

In the display device of the present invention, the second substrate terminal and a circuit board terminal provided on the circuit board are connected via an anisotropic conductive material.

According to the above configuration, the second substrate and the circuit board can be electrically connected with ease.

In the display device of the present invention, the anisotropic conductive material is a connector in which conductive strips and insulating strips are formed in a stripe pattern.

The connector with the above configuration (zebra connector) is low cost, and does not require precise alignment, and therefore, it is possible to electrically connect the terminals simply by stacking the second substrate terminal, the connector, and the circuit board terminal in this order. As a result, a display device that can suppress rises in the production unit cost and that has high productivity can be attained.

In the display device of the present invention, the second substrate terminal is provided along one side of a periphery of the second substrate.

According to the above configuration, the second substrate terminals are formed in a concentrated manner along one side of the second substrate, so it is possible to connect a plurality of second substrate terminals to circuit board terminals with ease through one connector. As a result, a display device that can suppress rises in the production unit cost and that has high productivity can be attained.

### INDUSTRIAL APPLICABILITY

The present invention can be applied to display devices such as liquid crystal display devices or organic EL display devices.

### DESCRIPTION OF REFERENCE CHARACTERS

1 liquid crystal display device (display device)
2 TFT substrate (first substrate)
3 opposite substrate (second substrate)
4, 4a, 17 input terminal
5 external circuit board (circuit board)
6 output terminal (circuit board terminal)
7 conductive strip
8 insulating strip
9 zebra connector (connector)
10 display panel
11 display region
12 scanning signal line driver circuit (driver circuit)
13 data signal line driver circuit (driver circuit)
14 wiring line
15, 15a second electrode pad
16 opposite electrode
18, 18a first electrode pad
19 sealing material
19a conductive member
20 pixel electrode
21 TFT element
28 interlayer insulating film (insulating layer)
29, 35 contact hole
31 protective insulating film (insulating layer)
32 through-hole (contact hole)
36 intermediate metal film
38 protective circuit
40 black matrix
41 common transfer electrode
42 common transfer wiring line
44 color filter
45 protruding part
50 uneven part
51 pixel circuit
GL scanning signal line
SL data signal line

1. A display panel, comprising:
a first substrate and a second substrate disposed to face each other;
a first electrode pad provided on a surface of the first substrate facing the second substrate; and
a second electrode pad provided on a surface of the second substrate facing the first substrate,
wherein at least a portion of the first electrode pad and the second electrode pad overlap in a plan view,
wherein the second substrate has a black matrix formed on the surface thereof facing the first substrate,
wherein the second electrode pad is provided in a location that does not overlap the black matrix in a plan view, and
wherein the first electrode pad is provided on a protruding part formed on the first substrate.

2. The display panel according to claim 1, further comprising an insulating layer provided in the first substrate,
wherein the protruding part has a higher surface due to an increased thickness of the insulating layer.

3. The display panel according to claim 1, wherein a thickness of the protruding part is substantially the same as that of the black matrix.

4. The display panel according to claim 1, wherein the first substrate and the second substrate are bonded to each other via a sealing material,
wherein the sealing material contains a conductive member, and
wherein the first electrode pad and the second electrode pad are connected via the conductive member.

5. The display panel according to claim 4, further comprising a pixel circuit and a driver circuit in the first substrate, the driver circuit being provided for driving the pixel circuit,
wherein the driver circuit is connected to the first electrode pad, and
wherein the driver circuit is connected to the second electrode pad via the first electrode pad and the conductive member.

6. The display panel according to claim 5, wherein the driver circuit is formed monolithically.

7. The display panel according to claim 5, wherein the driver circuit and the first electrode pad are connected via a protective circuit.

8. The display panel according to claim 7, wherein the protective circuit comprises a resistor, and
wherein the first electrode pad and the resistor overlap each other through an insulating layer in a plan view.

9. The display panel according to claim 7, wherein the protective circuit comprises a resistor, a transistor, and a capacitor.

10. The display panel according to claim 4, further comprising:
an opposite electrode in the second substrate; and
a common transfer electrode in the first substrate,
wherein the common transfer electrode is connected to the first electrode pad, and
wherein the opposite electrode and the common transfer electrode are connected via the conductive member.

11. The display panel according to claim 10, wherein the second electrode pad and the opposite electrode are formed by patterning a same layer.

12. The display panel according to claim 1, further comprising:
a reflective pixel electrode in the first substrate; and
an uneven part between the first substrate and the pixel electrode,
wherein the protruding part and the uneven part are formed of a same material.

13. The display panel according to claim 12, wherein said material is a photosensitive resin.

14. A display device, comprising:
the display panel according to claim 1; and
a circuit board,
wherein the second substrate has a second substrate terminal connected to the second electrode pad, the second substrate terminal being connected to the circuit board, and
wherein the second substrate terminal has a part that does not overlap the first substrate in a plan view.

15. The display device according to claim 14, wherein the second substrate terminal and a circuit board terminal provided on the circuit board are connected via an anisotropic conductive material.

16. The display device according to claim 15, wherein said anisotropic conductive material is a connector in which conductive strips and insulating strips are formed in a stripe pattern.

17. The display device according to claim 14, wherein the second substrate terminal is provided along one side of a periphery of the second substrate.
